(19) United States
(12) Patent Application Publication
(10) Pub. No.: US 2025/0183227 A1
(43) Pub. Date: Jun. 5, 2025

(54) HIGH-DENSITY SEMICONDUCTOR CHIP PACKAGE

(71) Applicant: Micron Technology, Inc., Boise, ID (US)

(72) Inventors: Kelvin Aik Boo TAN, Singapore (SG); Seng Kim YE, Singapore (SG); Hong Wan NG, Singapore (SG); See Hiong LEOW, Singapore (SG); Ling PAN, Singapore (SG); Chin Hui CHONG, Singapore (SG)

(21) Appl. No.: 18/932,922

(22) Filed: Oct. 31, 2024

Related U.S. Application Data
(60) Provisional application No. 63/604,443, filed on Nov. 30, 2023.

(51) Int. Cl. H01L 25/065; H01L 23/00; H01L 23/31; H01L 23/498; H01L 23/538; H01L 25/00; H10B 80/00

(52) U.S. Cl. CPC H01L 25/0652; H01L 23/49816; H01L 23/5386; H01L 24/48; H01L 24/49; H01L 25/50; H01L 23/3107; H01L 2224/48145; H01L 2224/48227; H01L 2224/49112; H01L 2225/06506; H01L 2225/0651; H01L 2225/06562; H10B 80/00

(57) ABSTRACT

A semiconductor device assembly includes a circuit substrate including a first substrate surface and a second substrate surface; a first die stack, a second die stack, and a third die stack arranged on the first substrate surface; a plurality of conductive interconnect structures coupled to the second substrate surface; a first signal channel including a first subset of the plurality conductive interconnect structures; and a second signal channel including a second subset of the plurality conductive interconnect structures. The first signal channel is electrically coupled to a first plurality of die stacks including at least two of the first die stack, the second die stack, and the third die stack. The second signal channel is electrically coupled to a second plurality of die stacks including at least two of the first die stack, the second die stack, and the third die stack.

### CROSS REFERENCE TO RELATED APPLICATION

This patent application claims priority to U.S. Provisional Patent Application No. 63/604,443, filed on Nov. 30, 2023, and entitled “HIGH-DENSITY SEMICONDUCTOR CHIP PACKAGE,” The disclosure of the prior application is considered part of and is incorporated by reference into this patent application.

### TECHNICAL FIELD

The present disclosure generally relates to semiconductor devices and methods of forming semiconductor devices. For example, the present disclosure relates to high-density semiconductor chip packages.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., a circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3A shows a cross-section of a semiconductor device assembly according to one or more implementations.

FIG. 3B shows a cross-section of a semiconductor device assembly according to one or more implementations.

FIG. 3C shows a cross-section of a semiconductor device assembly according to one or more implementations.

FIG. 4 shows a cross-section of a semiconductor device assembly according to one or more implementations.

FIG. 5 shows a cross-section of a semiconductor device assembly according to one or more implementations.

FIG. 6 is a flowchart of an example process associated with a high-density semiconductor device assembly.

### DETAILED DESCRIPTION

A semiconductor package assembly, such as a semiconductor chip package, may be one type of semiconductor device assembly that is structured to house one or more dies. Typically, one or more dies are attached to a die side of a circuit substrate, and a package casing, such as a molded compound casing, is disposed over the die side of the circuit substrate to encapsulate the one or more dies. Conductive interconnect structures, such as solder balls, may be attached to a back-side of the circuit substrate to provide electrical connections to the one or more dies.

A die stack may be a vertical stack of two or more dies, with one die arranged on top of another. A common design approach is to have a single die stack arranged within a package outline of a semiconductor chip package. All dies of the single die stack are then coupled to a single signal channel. However, this design approach is limited to how many dies can be arranged on a circuit board. In other words, a density of the dies within a system, such as a memory system, is limited by the number of semiconductor chip packages that can be arranged on the circuit board, with each semiconductor chip package having only one die stack and the one die stack being associated with one signal channel. Semiconductor chip packages that provide higher density die configurations may be needed to meet growing processing and memory demands. In addition, semiconductor chip packages that provide higher density die configurations at lower manufacturing costs may also be desired.

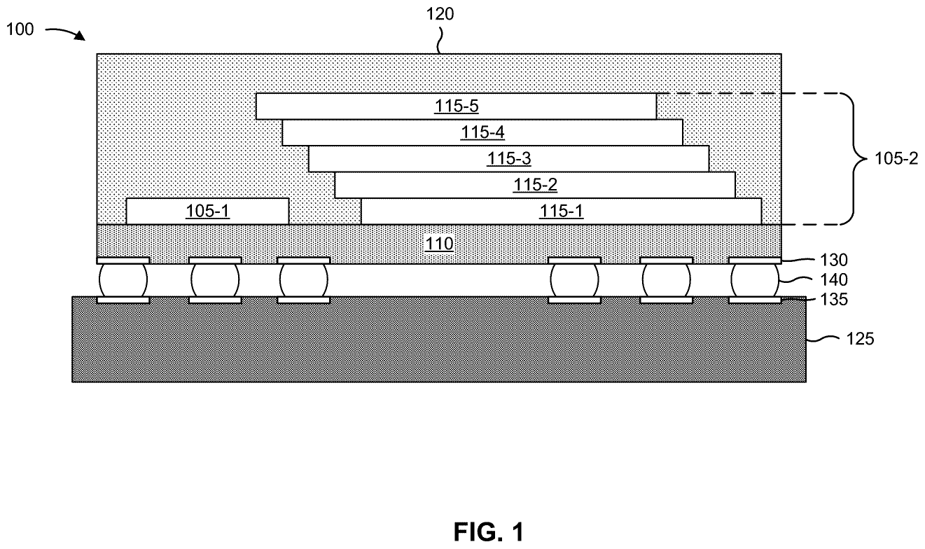

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a shingle stack (e.g., with die edges that are not aligned, which provides space for wire bonding near the edges of the dies 115), in some implementations, the dies 115 may be stacked in a different arrangement, such as a straight stack (e.g., with aligned die edges).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system. For example, the interconnections between an integrated circuit 105 and the substrate 110 (e.g., solder balls 140 or another type of conductive interconnect structures) may provide a plurality of signal channels, such as data channels or memory channels used to transmit data to or from one or more semiconductor dies. In some implementations, different subsets of conductive interconnect structures are allocated to different signal channels, and different signal channels are connected to different subsets of semiconductor dies.

As indicated above, FIG. 1 is provided as an example. Other examples may differ from what is described with regard to FIG. 1.

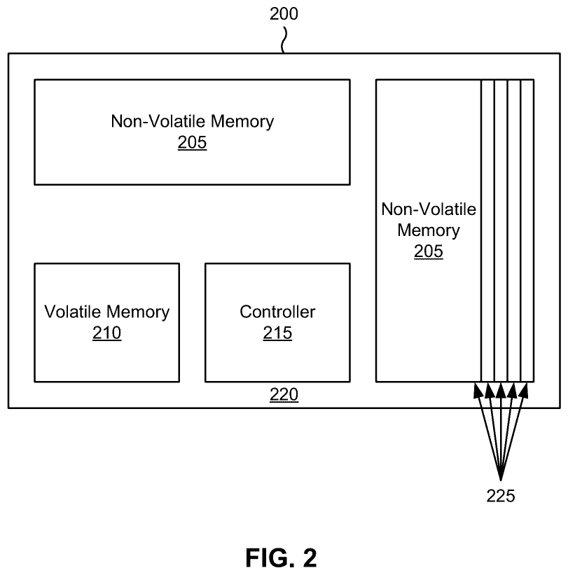

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

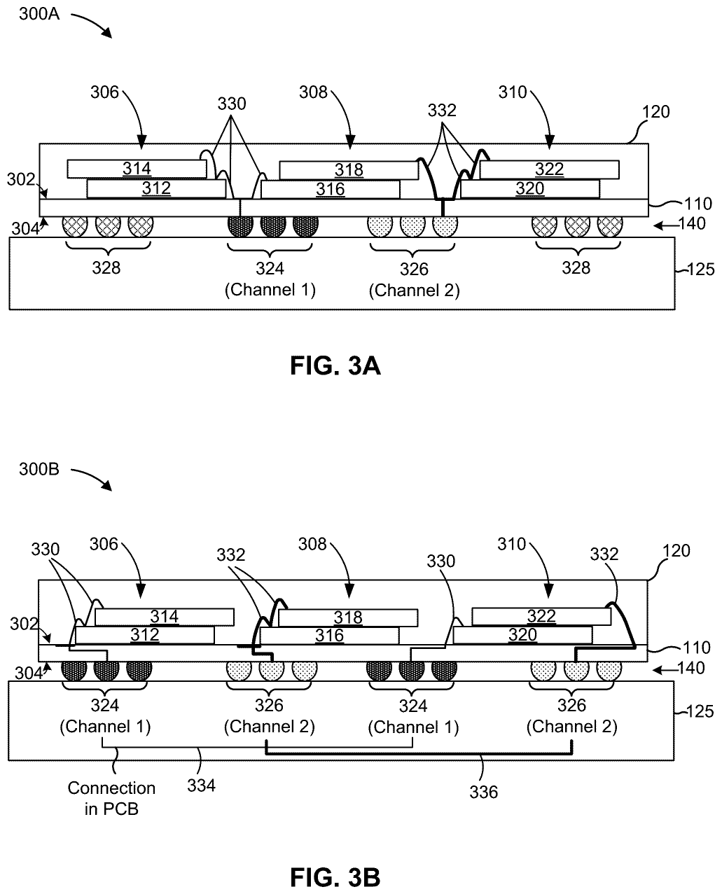

FIG. 3A shows a cross-section of a semiconductor device assembly 300A according to one or more implementations. The semiconductor device assembly 300A may be a semiconductor chip package. In some implementations, the semiconductor device assembly 300A may be a memory device (e.g., a semiconductor chip package that houses a plurality of memory dies).

The semiconductor device assembly 300A includes the substrate 110 (e.g., a circuit substrate) and a plurality of conductive interconnect structures, such as solder balls 140, that may be used to electrically connect the substrate 110 to the circuit board 125. Additionally, the semiconductor device assembly 300A includes the casing 120 (e.g., a package casing) that protects internal components of the semiconductor device assembly 300A.

The substrate 110 may include a first substrate surface 302 and a second substrate surface 304 arranged opposite to the first substrate surface 302. The semiconductor device assembly 300A may include a first die stack 306, a second die stack 308, and a third die stack 310 arranged on the first substrate surface 302. The first die stack 306, the second die stack 308, and the third die stack 310 are laterally separated from each other on the first substrate surface 302. The first die stack 306 includes a first plurality of dies, including at least a first die 312 arranged on the first substrate surface 302 and a second die 314 arranged on the first die 312. The second die stack 308 includes a second plurality of dies, including at least a third die 316 arranged on the first substrate surface 302 and a fourth die 318 arranged on the third die 316. The third die stack 308 includes a third plurality of dies, including at least a fifth die 320 arranged on the first substrate surface 302 and a sixth die 322 arranged on the fifth die 320. The casing 120 may be disposed over the first substrate surface 302 in order to encapsulate the first die stack 306, the second die stack 308, and the third die stack 310, and to cover at least part of the first substrate surface 302.

The first plurality of dies, the second plurality of dies, and the third plurality of dies may be memory dies. For example, the memory dies may be NAND memory dies or dynamic random-access memory (DRAM) dies. Data may be written to or read from the first plurality of dies, the second plurality of dies, and/or the third plurality of dies using a plurality of signal channels (e.g., a plurality of data channels). The plurality of conductive interconnect structures (e.g., solder balls 140) may be coupled to the second substrate surface 304 and may provide electrical connections to the first die stack 306, the second die stack 308, and the third die stack 310. The plurality of conductive interconnect structures may be allocated to the plurality of signal channels.

For example, the semiconductor device assembly 300A may include a first signal channel (Channel 1) and a second signal channel (Channel 2). The first signal channel (Channel 1) may include a first subset of conductive interconnect structures 324 (e.g., a first plurality of conductive interconnect structures) of the plurality of conductive interconnect structures. The second signal channel (Channel 2) may include a second subset of conductive interconnect structures 326 (e.g., a second plurality of conductive interconnect structures) of the plurality of conductive interconnect structures. In other words, the first subset of conductive interconnect structures 324 may be part of the first signal channel (Channel 1) that may additionally include respective conductive traces in the substrate 110 to the circuit board 125 and respective bond wires that are electrically coupled to respective dies of the semiconductor device assembly 300A. The second subset of conductive interconnect structures 326 may be part of the second signal channel (Channel 2) that may additionally include respective conductive traces in the substrate 110 to the circuit board 125 and respective bond wires that are electrically coupled to respective dies of the semiconductor device assembly 300A.

The plurality of conductive interconnect structures may include subsets of dummy structures 328 that are not electrically connected to the dies. Instead, the subsets of dummy structures 328 may provide structural support to the substrate 110 and may provide a mechanical coupling to the circuit board 125.

The first signal channel (Channel 1) may be electrically coupled to a first plurality of die stacks comprising at least two of the first die stack 306, the second die stack 308, and the third die stack 310. The second signal channel (Channel 2) may be electrically coupled to a second plurality of die stacks comprising at least two of the first die stack 306, the second die stack 308, and the third die stack 310. For example, each signal channel may be electrically coupled to three or more dies of the semiconductor device assembly 300A, with each signal channel being coupled to a different group of dies that are mutually exclusive from each other. In other words, each die may be coupled to only one signal channel. Thus, the first signal channel (Channel 1) may be electrically coupled to at least three dies of the first plurality of die stacks, the second signal channel (Channel 2) may be electrically coupled to at least three dies of the second plurality of die stacks, and the at least three dies of the first plurality of die stacks may be entirely different from the at least three dies of the second plurality of die stacks.

The first signal channel (Channel 1) may be electrically coupled to each die of the first plurality of dies (e.g., the first die 312 and the second die 314) of the first die stack 306. Additionally, the first signal channel (Channel 1) may be electrically coupled to a first die (e.g., the third die 316) of the second plurality of dies of the second die stack 308. Thus, the first plurality of die stacks may include the first die stack 306 and the second die stack 308, but not the third die stack 310. The second signal channel (Channel 2) may be electrically coupled to each die of the third plurality of dies (e.g., the fifth die 320 and the sixth die 322) of the third die stack 310. Additionally, the second signal channel (Channel 2) may be electrically coupled to a second die (e.g., the fourth die 318) of the second plurality of dies of the second die stack 308. Thus, the second plurality of die stacks may include the second die stack 308 and the third die stack 310, but not the first die stack 306.

In addition, the first signal channel (Channel 1) may include a first plurality of bond wires 330 connected to the first subset of conductive interconnect structures 324 and the first plurality of die stacks. In other words, the first plurality of bond wires 330 may be coupled to one or more conductive traces of the substrate 110 and to the first die 312, the second die 314, and the third die 316. In addition, the second signal channel (Channel 2) may include a second plurality of bond wires 332 connected to the second subset of conductive interconnect structures 326 and the second plurality of die stacks. In other words, the second plurality of bond wires 332 may be coupled to one or more conductive traces of the substrate 110 and to the fourth die 318, the fifth die 320, and the sixth die 322.

Accordingly, the semiconductor device assembly 300A may include multiple die stacks, including the first die stack 306, the second die stack 308, and the third die stack 310. In addition, the semiconductor device assembly 300A may include the first data channel (e.g., Channel 1) including the first plurality of conductive interconnect structures (e.g., the first subset of conductive interconnect structures 324) coupled to the second substrate surface 304, and the second data channel (e.g., Channel 2) including the second plurality of conductive interconnect structures (e.g., second subset of conductive interconnect structures 326) coupled to the second substrate surface 304. The first data channel may be electrically coupled to the first plurality of die stacks comprising at least two of the first die stack, the second die stack, and the third die stack. The second data channel may be electrically coupled to the second plurality of die stacks comprising at least two of the first die stack, the second die stack, and the third die stack. The first plurality of die stacks and the second plurality of die stacks may include different mutually exclusive or disjoint sets of dies. As a result, the semiconductor device assembly 300A may support a higher density of dies within a package outline than would otherwise be possible. For memory devices, higher memory densities are possible with more memory dies being included in a single semiconductor chip package. Moreover, multiple signal channels (e.g., data channels) provided in the single semiconductor chip package enable different sets of dies within the single semiconductor chip package to be accessed for writing and/or reading operations.

As indicated above, FIG. 3A is provided as an example. Other examples may differ from what is described with regard to FIG. 3A. The number and arrangement of components shown in FIG. 3A are provided as an example. In practice, there may be additional components, fewer components, different components, or differently arranged components than those shown in FIG. 3A.

FIG. 3B shows a cross-section of a semiconductor device assembly 300B according to one or more implementations. The semiconductor device assembly 300B may be a semiconductor chip package. In some implementations, the semiconductor device assembly 300B may be a memory device (e.g., a semiconductor chip package that houses a plurality of memory dies).

The semiconductor device assembly 300B may be similar to the semiconductor device assembly 300A described in connection with FIG. 3A, with the exception of some differences.

First, the first subset of conductive interconnect structures 324 associated with the first signal channel (Channel 1) may include additional conductive interconnect structures that are laterally distributed at the second substrate surface 304 to provide electrical connections to die stacks that are laterally distributed at the first substrate surface 302. The first subset of conductive interconnect structures 324 may be connected by conductive traces 334 in the circuit board 125. Similarly, the second subset of conductive interconnect structures 326 associated with the second signal channel (Channel 2) may include additional conductive interconnect structures that are laterally distributed at the second substrate surface 304 to provide electrical connections to die stacks that are laterally distributed at the first substrate surface 302. The second subset of conductive interconnect structures 326 may be connected by conductive traces 336 in the circuit board 125.

Second, the first signal channel (Channel 1) may be electrically coupled to each die of the first plurality of dies and a first die of the third plurality of dies, and the second signal channel (Channel 2) may be electrically coupled to each die of the second plurality of dies and a second die of the third plurality of dies.

For example, the first signal channel (Channel 1) may be electrically coupled to each die of the first plurality of dies (e.g., the first die 312 and the second die 314) of the first die stack 306. Additionally, the first signal channel (Channel 1) may be electrically coupled to a first die (e.g., the fifth die 320) of the third plurality of dies of the third die stack 310. Thus, the first plurality of die stacks may include the first die stack 306 and the third die stack 310, but not the second die stack 308. The second signal channel (Channel 2) may be electrically coupled to each die of the second plurality of dies (e.g., the third die 316 and the fourth die 318) of the second die stack 308. Additionally, the second signal channel (Channel 2) may be electrically coupled to a second die (e.g., the sixth die 322) of the third plurality of dies of the third die stack 310. Thus, the second plurality of die stacks may include the second die stack 308 and the third die stack 310, but not the first die stack 306.

As a result, the semiconductor device assembly 300B may support a higher density of dies within a package outline than would otherwise be possible. For memory devices, higher memory densities are possible with more memory dies being included in a single semiconductor chip package. Moreover, multiple signal channels (e.g., data channels) provided in the single semiconductor chip package enable different sets of dies within the single semiconductor chip package to be accessed for writing and/or reading operations.

As indicated above, FIG. 3B is provided as an example. Other examples may differ from what is described with regard to FIG. 3B. The number and arrangement of components shown in FIG. 3B are provided as an example. In practice, there may be additional components, fewer components, different components, or differently arranged components than those shown in FIG. 3B.

FIG. 3C shows a cross-section of a semiconductor device assembly 300C according to one or more implementations. The semiconductor device assembly 300C may be a semiconductor chip package. In some implementations, the semiconductor device assembly 300C may be a memory device (e.g., a semiconductor chip package that houses a plurality of memory dies).

The semiconductor device assembly 300C may be similar to the semiconductor device assembly 300B described in connection with FIG. 3B, with the exception of some differences.

The first signal channel (Channel 1) may be electrically coupled to a first die of the first plurality of dies of the first die stack 306, a first die of the second plurality of dies of the second die stack 308, and a third die of the third plurality of dies of the third die stack 308. For example, the first signal channel (Channel 1) may be electrically coupled to a first die (e.g., the first die 312) of the first plurality of dies, a first die (e.g., the fourth die 318) of the second plurality of dies, and a first die (e.g., the fifth die 320) of the third plurality of dies.

The second signal channel (Channel 2) may be electrically coupled to a second die of the first plurality of dies of the first die stack 306, a second die of the second plurality of dies of the second die stack 308, and a second die of the third plurality of dies of the third die stack 310. For example, the second signal channel (Channel 2) may be electrically coupled to a second die (e.g., the second die 314) of the first plurality of dies, a second die (e.g., the third die 316) of the second plurality of dies, and a second die (e.g., the sixth die 322) of the third plurality of dies.

As a result, the semiconductor device assembly 300C may support a higher density of dies within a package outline than would otherwise be possible. For memory devices, higher memory densities are possible with more memory dies being included in a single semiconductor chip package. Moreover, multiple signal channels (e.g., data channels) provided in the single semiconductor chip package enable different sets of dies within the single semiconductor chip package to be accessed for writing and/or reading operations.

As indicated above, FIG. 3C is provided as an example. Other examples may differ from what is described with regard to FIG. 3C. The number and arrangement of components shown in FIG. 3C are provided as an example. In practice, there may be additional components, fewer components, different components, or differently arranged components than those shown in FIG. 3C.

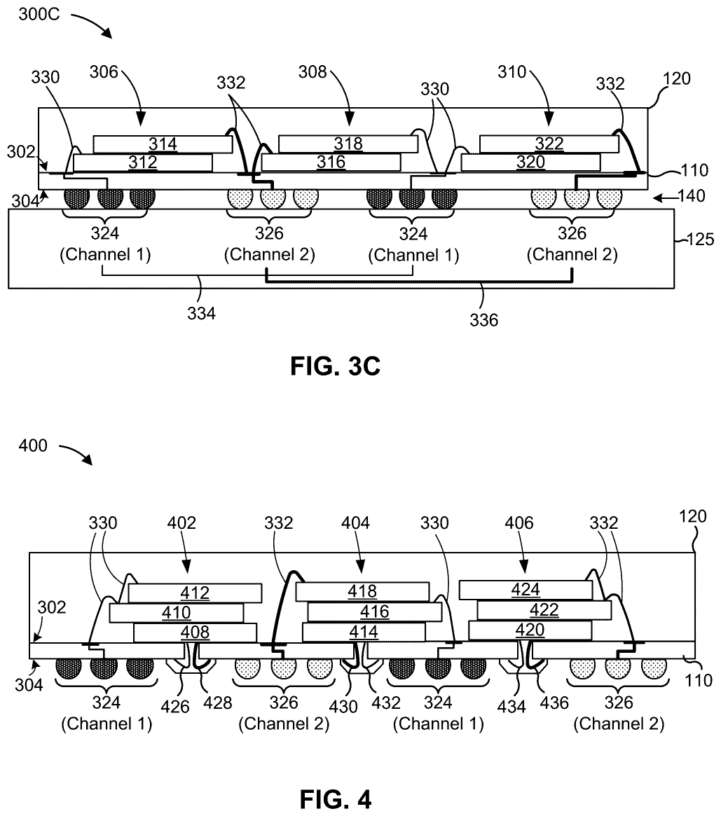

FIG. 4 shows a cross-section of a semiconductor device assembly 400 according to one or more implementations. The semiconductor device assembly 400 may be a semiconductor chip package. In some implementations, the semiconductor device assembly 400 may be a memory device (e.g., a semiconductor chip package that houses a plurality of memory dies).

The semiconductor device assembly 400 may include a first die stack 402, a second die stack 404, and a third die stack 406 arranged on the first substrate surface 302. The first die stack 402, the second die stack 404, and the third die stack 406 are laterally separated from each other on the first substrate surface 302. The first die stack 402 includes a first plurality of dies, including at least a first die 408 arranged on the first substrate surface 302, a second die 410 arranged on the first die 408, and a third die 412 arranged on the second die 410. The second die stack 404 includes a second plurality of dies, including at least a fourth die 414 arranged on the first substrate surface 302, a fifth die 416 arranged on the fourth die 414, and a sixth die 418 arranged on the fifth die 416. The third die stack 404 includes a third plurality of dies, including at least a seventh die 420 arranged on the first substrate surface 302, an eighth die 422 arranged on the seventh die 420, and a ninth die 424 arranged on the eighth die 422. The casing 120 may be disposed over the first substrate surface 302 in order to encapsulate the first die stack 402, the second die stack 404, and the third die stack 406, and to cover at least part of the first substrate surface 302. Thus, each die stack 402, 404, and 406 may include three or more dies.

The first plurality of dies, the second plurality of dies, and the third plurality of dies may be memory dies. For example, the memory dies may be NAND memory dies or DRAM memory dies. Data may be written to or read from the first plurality of dies, the second plurality of dies, and the third plurality of dies using a plurality of signal channels (e.g., a plurality of data channels). The plurality of conductive interconnect structures (e.g., solder balls 140) may be coupled to the second substrate surface 304 and may provide electrical connections to the first die stack 402, the second die stack 404, and the third die stack 406. The plurality of conductive interconnect structures may be allocated to the plurality of signal channels.

For example, the semiconductor device assembly 400 may include the first signal channel (Channel 1) and the second signal channel (Channel 2). The first signal channel (Channel 1) may include the first subset of conductive interconnect structures 324 (e.g., a first plurality of conductive interconnect structures) of the plurality of conductive interconnect structures. The second signal channel (Channel 2) may include the second subset of conductive interconnect structures 326 (e.g., a second plurality of conductive interconnect structures) of the plurality of conductive interconnect structures. In other words, the first subset of conductive interconnect structures 324 may be part of the first signal channel (Channel 1) that may additionally include respective conductive traces in the substrate 110 to the circuit board 125 (not illustrated) and respective bond wires that are electrically coupled to respective dies of the semiconductor device assembly 400. The second subset of conductive interconnect structures 326 may be part of the second signal channel (Channel 2) that may additionally include respective conductive traces in the substrate 110 to the circuit board 125 (not illustrated) and respective bond wires that are electrically coupled to respective dies of the semiconductor device assembly 400.

The first signal channel (Channel 1) may be electrically coupled to a first plurality of die stacks comprising at least two of the first die stack 402, the second die stack 404, and the third die stack 406. The second signal channel (Channel 2) may be electrically coupled to a second plurality of die stacks comprising at least two of the first die stack 402, the second die stack 404, and the third die stack 406. For example, each signal channel may be electrically coupled to three or more dies of the semiconductor device assembly 400, with each signal channel being coupled to a different group of dies that are mutually exclusive from each other. In other words, each die may be coupled to only one signal channel. Thus, the first signal channel (Channel 1) may be electrically coupled to at least three dies of the first plurality of die stacks, the second signal channel (Channel 2) may be electrically coupled to at least three dies of the second plurality of die stacks, and the at least three dies of the first plurality of die stacks may be entirely different from the at least three dies of the second plurality of die stacks. In this example, the first signal channel (Channel 1) and the second signal channel (Channel 2) are each coupled to at least four dies. The at least four dies of the first plurality of die stacks are different from the at least four dies of the second plurality of die stacks. In some implementations, the first signal channel (Channel 1) may be coupled to three dies and the second signal channel (Channel 2) may be coupled to five dies, or vice versa.

The first signal channel (Channel 1) may be electrically coupled to each die of the first plurality of dies (e.g., the first die 408, the second die 410, and the third die 412) of the first die stack 402. Additionally, the first signal channel (Channel 1) may be electrically coupled to a first die and a second die (e.g., the fourth die 414 and the fifth die 416) of the second plurality of dies of the second die stack 404. Thus, the first plurality of die stacks may include the first die stack 402 and the second die stack 404, but not the third die stack 406. The second signal channel (Channel 2) may be electrically coupled to each die of the third plurality of dies (e.g., the seventh die 420, the eighth die 422, and the ninth die 424) of the third die stack 406. Additionally, the second signal channel (Channel 2) may be electrically coupled to a third die (e.g., the sixth die 418) of the second plurality of dies of the second die stack 404. Thus, the second plurality of die stacks may include the second die stack 404 and the third die stack 406, but not the first die stack 402.

In addition, the first signal channel (Channel 1) may include the first plurality of bond wires 330 connected to the first subset of conductive interconnect structures 324 and the first plurality of die stacks. In other words, the first plurality of bond wires 330 may be coupled to one or more conductive traces of the substrate 110 and to respective dies of the first plurality of die stacks. In addition, the second signal channel (Channel 2) may include the second plurality of bond wires 332 connected to the second subset of conductive interconnect structures 326 and the second plurality of die stacks. In other words, the second plurality of bond wires 332 may be coupled to one or more conductive traces of the substrate 110 and to respective dies of the second plurality of die stacks.

Each die stack 402, 404, and 406 may have a board-on-chip configuration and a chip-on-board configuration. For example, the first die 408, the fourth die 414, and the seventh die 420 may have the board-on-chip configuration, which utilizes a face-down type of wire bonding technology. The first die 408, the fourth die 414, and the seventh die 420 may be electrically coupled to a respective conductive interconnect structure by a bond wire that extends through a through-hole of the substrate 110. An encapsulation, such as a mold compound, a plastic (e.g., an epoxy plastic), a ceramic, or another type of material, may be used to fill the through-hole and encapsulate the bond wire for protection of the dies, the substrate 110, and the bond wires.

For example, a bond wire 426 may electrically couple the first die 408 to the first subset of conductive interconnect structures 324. Alternatively, a bond wire 428 may electrically couple the first die 408 to the second subset of conductive interconnect structures 326. A bond wire 430 may electrically couple the fourth die 414 to the first subset of conductive interconnect structures 324. Alternatively, a bond wire 432 may electrically couple the fourth die 414 to the second subset of conductive interconnect structures 326. A bond wire 434 may electrically couple the seventh die 420 to the first subset of conductive interconnect structures 324. Alternatively, a bond wire 436 may electrically couple the seventh die 420 to the second subset of conductive interconnect structures 326.

The second die 410, the third die 412, the fifth die 416, the sixth die 418, the eighth die 422, and the ninth die 424 may have the chip-on-board configuration, which utilizes a face-up type of wire bonding technology. Thus, the second die 410, the third die 412, the fifth die 416, the sixth die 418, the eighth die 422, and the ninth die 424 may be electrically coupled to respective conductive interconnect structures by the first plurality of bond wires 330 or the second plurality of bond wires 332.

As a result, the semiconductor device assembly 400 may support a higher density of dies within a package outline than would otherwise be possible. For memory devices, higher memory densities are possible with more memory dies being included in a single semiconductor chip package. Moreover, multiple signal channels (e.g., data channels) provided in the single semiconductor chip package enable different sets of dies within the single semiconductor chip package to be accessed for writing and/or reading operations.

As indicated above, FIG. 4 is provided as an example. Other examples may differ from what is described with regard to FIG. 4. The number and arrangement of components shown in FIG. 4 are provided as an example. In practice, there may be additional components, fewer components, different components, or differently arranged components than those shown in FIG. 4.

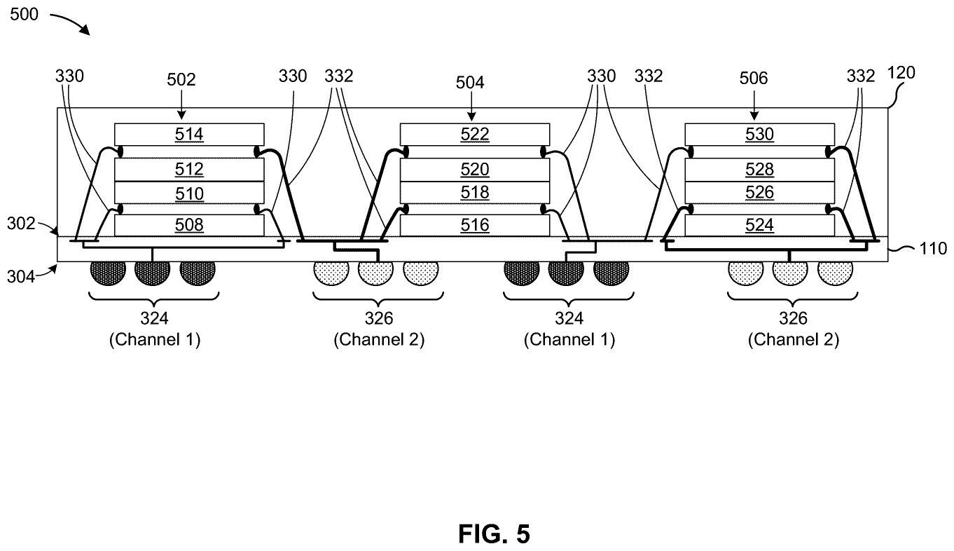

FIG. 5 shows a cross-section of a semiconductor device assembly 500 according to one or more implementations. The semiconductor device assembly 500 may be a semiconductor chip package. In some implementations, the semiconductor device assembly 500 may be a memory device (e.g., a semiconductor chip package that houses a plurality of memory dies).

The semiconductor device assembly 500 may include a first die stack 502, a second die stack 504, and a third die stack 506 arranged on the first substrate surface 302. The first die stack 502, the second die stack 504, and the third die stack 506 are laterally separated from each other on the first substrate surface 302. The first die stack 502 includes a first plurality of dies, including at least a first die 508 arranged on the first substrate surface 302, a second die 510 arranged on the first die 508, and a third die 512 arranged on the second die 510, and a fourth 514 die arranged on the third die 512. The second die stack 504 includes a second plurality of dies, including at least a fifth die 516 arranged on the first substrate surface 302, a sixth die 518 arranged on the fifth die 516, a seventh die 520 arranged on the sixth die 518, and an eighth die 522 arranged on the seventh die 520. The third die stack 504 includes a third plurality of dies, including at least a ninth die 524 arranged on the first substrate surface 302, a tenth die 526 arranged on the ninth die 524, an eleventh die 528 arranged on the tenth die 526, and a twelfth die 530 arranged on the eleventh die 528. The casing 120 may be disposed over the first substrate surface 302 in order to encapsulate the first die stack 502, the second die stack 504, and the third die stack 506, and to cover at least part of the first substrate surface 302. Thus, each die stack 502, 504, and 506 may include three or more dies. In this example, each die stack 502, 504, and 506 includes four dies.

The first plurality of dies, the second plurality of dies, and the third plurality of dies may be memory dies. For example, the memory dies may be NAND memory dies or DRAM memory dies. Data may be written to or read from the first plurality of dies, the second plurality of dies, and the third plurality of dies using a plurality of signal channels (e.g., a plurality of data channels). The plurality of conductive interconnect structures (e.g., solder balls 140) may be coupled to the second substrate surface 304 and may provide electrical connections to the first die stack 502, the second die stack 504, and the third die stack 506. The plurality of conductive interconnect structures may be allocated to the plurality of signal channels.

For example, the semiconductor device assembly 500 may include the first signal channel (Channel 1) and the second signal channel (Channel 2). The first signal channel (Channel 1) may include the first subset of conductive interconnect structures 324 (e.g., a first plurality of conductive interconnect structures) of the plurality of conductive interconnect structures. The second signal channel (Channel 2) may include the second subset of conductive interconnect structures 326 (e.g., a second plurality of conductive interconnect structures) of the plurality of conductive interconnect structures. In other words, the first subset of conductive interconnect structures 324 may be part of the first signal channel (Channel 1) that may additionally include respective conductive traces in the substrate 110 to the circuit board 125 (not illustrated) and respective bond wires that are electrically coupled to respective dies of the semiconductor device assembly 500. The second subset of conductive interconnect structures 326 may be part of the second signal channel (Channel 2) that may additionally include respective conductive traces in the substrate 110 to the circuit board 125 (not illustrated) and respective bond wires that are electrically coupled to respective dies of the semiconductor device assembly 500.

The first signal channel (Channel 1) may be electrically coupled to a first plurality of die stacks comprising at least two of the first die stack 502, the second die stack 504, and the third die stack 506. The second signal channel (Channel 2) may be electrically coupled to a second plurality of die stacks comprising at least two of the first die stack 502, the second die stack 504, and the third die stack 506. For example, each signal channel may be electrically coupled to three or more dies of the semiconductor device assembly 500, with each signal channel being coupled to a different group of dies that are mutually exclusive from each other. In other words, each die may be coupled to only one signal channel. Thus, the first signal channel (Channel 1) may be electrically coupled to at least three dies of the first plurality of die stacks, the second signal channel (Channel 2) may be electrically coupled to at least three dies of the second plurality of die stacks, and the at least three dies of the first plurality of die stacks may be entirely different from the at least three dies of the second plurality of die stacks. In this example, the first signal channel (Channel 1) and the second signal channel (Channel 2) are each coupled to at least six dies. The at least six dies of the first plurality of die stacks are different from the at least six dies of the second plurality of die stacks. In some implementations, the first signal channel (Channel 1) may be coupled to less than six dies (e.g., three to five dies) and the second signal channel (Channel 2) may be coupled to more than six dies, or vice versa.

The first plurality of dies of the first die stack 502 may include a first pair of face-to-face coupled dies arranged on the first substrate surface, and a second pair of face-to-face coupled dies arranged on the first pair of face-to-face coupled dies. For example, the first pair of face-to-face coupled dies may include the first and the second dies 508 and 510. The second pair of face-to-face coupled dies may include the third and the fourth dies 512 and 514.

The second plurality of dies of the second die stack 504 may include a third pair of face-to-face coupled dies arranged on the first substrate surface, and a fourth pair of face-to-face coupled dies arranged on the third pair of face-to-face coupled dies. For example, the third pair of face-to-face coupled dies may include the fifth and the sixth dies 516 and 518. The fourth pair of face-to-face coupled dies may include the seventh and the eighth dies 520 and 522.

The third plurality of dies of the third die stack 506 may include a fifth pair of face-to-face coupled dies arranged on the first substrate surface, and a sixth pair of face-to-face coupled dies arranged on the fifth pair of face-to-face coupled dies. For example, the fifth pair of face-to-face coupled dies may include the ninth and the tenth dies 524 and 526. The sixth pair of face-to-face coupled dies may include the eleventh and the twelfth dies 528 and 530.

The first signal channel (Channel 1) may be electrically coupled to the first, the second, the third, the sixth, the eighth, and the eleventh dies (e.g., dies 508, 510, 512, 518, 522, 528) by the first plurality of bond wires 330. The second signal channel (Channel 2) may be electrically coupled to the fourth, the fifth, the seventh, the ninth, the tenth, and the twelfth dies (e.g., dies 514, 516, 520, 524, 526, and 530) by the second plurality of bond wires 332. Thus, the first plurality of die stacks and the second plurality of die stacks may both include the first die stack 502, the second die stack 504, and the third die stack 506, but may be include different mutually exclusive or disjoint sets of dies.

In addition, the first signal channel (Channel 1) may include the first plurality of bond wires 330 connected to the first subset of conductive interconnect structures 324 and the first plurality of die stacks. In other words, the first plurality of bond wires 330 may be coupled to one or more conductive traces of the substrate 110 and to respective dies of the first plurality of die stacks. In addition, the second signal channel (Channel 2) may include the second plurality of bond wires 332 connected to the second subset of conductive interconnect structures 326 and the second plurality of die stacks. In other words, the second plurality of bond wires 332 may be coupled to one or more conductive traces of the substrate 110 and to respective dies of the second plurality of die stacks.

As a result, the semiconductor device assembly 500 may support a higher density of dies within a package outline than would otherwise be possible. For memory devices, higher memory densities are possible with more memory dies being included in a single semiconductor chip package. Moreover, multiple signal channels (e.g., data channels) provided in the single semiconductor chip package enable different sets of dies within the single semiconductor chip package to be accessed for writing and/or reading operations.

As indicated above, FIG. 5 is provided as an example. Other examples may differ from what is described with regard to FIG. 5. The number and arrangement of components shown in FIG. 5 are provided as an example. In practice, there may be additional components, fewer components, different components, or differently arranged components than those shown in FIG. 5.

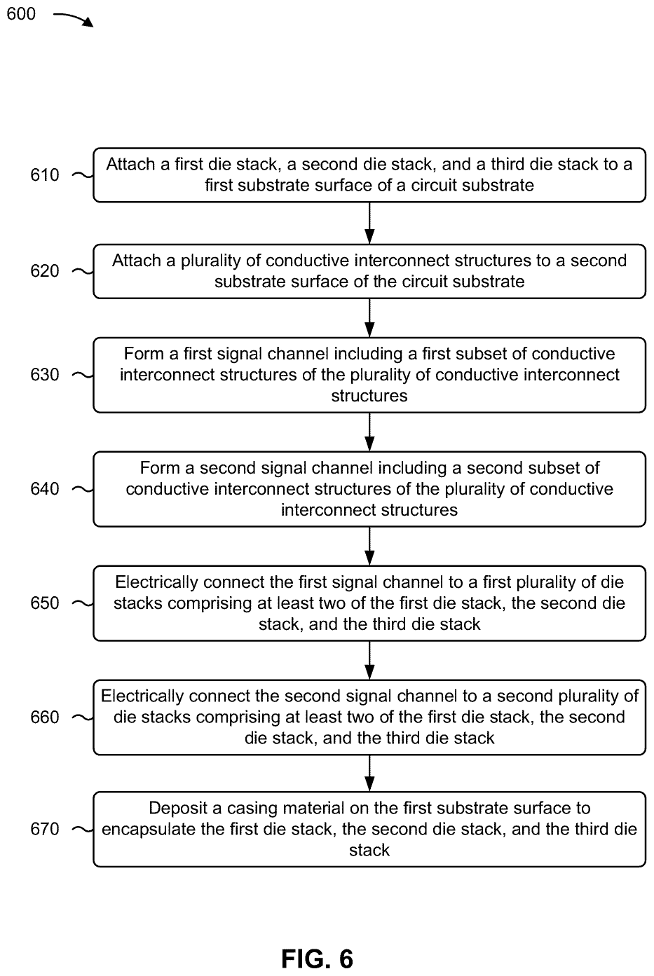

FIG. 6 is a flowchart of an example process 600 associated with a high density semiconductor device assembly. In some implementations, one or more process blocks of FIG. 6 are performed to manufacture a semiconductor device assembly (e.g., semiconductor device assembly 300A, 300B, 300C, 400, or 500). In some implementations, one or more process blocks of FIG. 6 are performed by another device or a group of devices.

As shown in FIG. 6, process 600 may include attaching a first die stack, a second die stack, and a third die stack to a first substrate surface of a circuit substrate (block 610). The first die stack may include a first plurality of dies, the second die stack may include a second plurality of dies, and the third die stack may include a third plurality of dies. The first die stack, the second die stack, and the third die stack may be laterally separated from each other on the first substrate surface.

As further shown in FIG. 6, process 600 may include attaching a plurality of conductive interconnect structures to a second substrate surface of the circuit substrate (block 620).

As further shown in FIG. 6, process 600 may include forming a first signal channel including a first subset of conductive interconnect structures of the plurality of conductive interconnect structures (block 630).

As further shown in FIG. 6, process 600 may include forming a second signal channel including a second subset of conductive interconnect structures of the plurality of conductive interconnect structures (block 640).

As further shown in FIG. 6, process 600 may include electrically connecting the first signal channel to a first plurality of die stacks comprising at least two of the first die stack, the second die stack, and the third die stack (block 650).

As further shown in FIG. 6, process 600 may include electrically connecting the second signal channel to a second plurality of die stacks comprising at least two of the first die stack, the second die stack, and the third die stack (block 660).

As further shown in FIG. 6, process 600 may include depositing a casing material on the first substrate surface to encapsulate the first die stack, the second die stack, and the third die stack (block 670).

Process 600 may include additional implementations, such as any single implementation or any combination of implementations described below and/or in connection with one or more other processes described elsewhere herein.

In a first implementation, the first signal channel may be electrically coupled to at least three dies of the first plurality of die stacks, the second signal channel may be electrically coupled to at least three dies of the second plurality of die stacks, and the at least three dies of the first plurality of die stacks may be different from the at least three dies of the second plurality of die stacks.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

In some implementations, a semiconductor device assembly includes a circuit substrate comprising a first substrate surface and a second substrate surface arranged opposite to the first substrate surface; a first die stack arranged on the first substrate surface, wherein the first die stack comprises a first plurality of dies; a second die stack arranged on the first substrate surface, wherein the second die stack comprises a second plurality of dies; a third die stack arranged on the first substrate surface, wherein the third die stack comprises a third plurality of dies; a package casing disposed over the first substrate surface, wherein the package casing encapsulates the first die stack, the second die stack, and the third die stack, and covers at least part of the first substrate surface; a plurality of conductive interconnect structures coupled to the second substrate surface; a first signal channel including a first subset of conductive interconnect structures of the plurality of conductive interconnect structures; and a second signal channel including a second subset of conductive interconnect structures of the plurality of conductive interconnect structures, wherein the first signal channel is electrically coupled to a first plurality of die stacks comprising at least two of the first die stack, the second die stack, and the third die stack, wherein the second signal channel is electrically coupled to a second plurality of die stacks comprising at least two of the first die stack, the second die stack, and the third die stack, and wherein the first die stack, the second die stack, and the third die stack are laterally separated from each other on the first substrate surface.

In some implementations, a memory device includes a circuit substrate comprising a first substrate surface and a second substrate surface arranged opposite to the first substrate surface; a first die stack arranged on the first substrate surface, wherein the first die stack comprises a first plurality of memory dies; a second die stack arranged on the first substrate surface, wherein the second die stack comprises a second plurality of memory dies; a third die stack arranged on the first substrate surface, wherein the third die stack comprises a third plurality of memory dies; a package casing disposed over the first substrate surface, wherein the package casing encapsulates the first die stack, the second die stack, and the third die stack, and covers at least part of the first substrate surface; a first data channel including a first plurality of conductive interconnect structures coupled to the second substrate surface; and a second data channel including a second plurality of conductive interconnect structures coupled to the second substrate surface, wherein the first data channel is electrically coupled to a first plurality of die stacks comprising at least two of the first die stack, the second die stack, and the third die stack, wherein the second data channel is electrically coupled to a second plurality of die stacks comprising at least two of the first die stack, the second die stack, and the third die stack, and wherein the first die stack, the second die stack, and the third die stack are laterally separated from each other on the first substrate surface.

In some implementations, a method includes attaching a first die stack, a second die stack, and a third die stack to a first substrate surface of a circuit substrate, wherein the first die stack comprises a first plurality of dies, the second die stack comprises a second plurality of dies, and the third die stack comprises a third plurality of dies, and wherein the first die stack, the second die stack, and the third die stack are laterally separated from each other on the first substrate surface; attaching a plurality of conductive interconnect structures to a second substrate surface of the circuit substrate; forming a first signal channel including a first subset of conductive interconnect structures of the plurality of conductive interconnect structures; forming a second signal channel including a second subset of conductive interconnect structures of the plurality of conductive interconnect structure; electrically connecting the first signal channel to a first plurality of die stacks comprising at least two of the first die stack, the second die stack, and the third die stack; electrically connecting the second signal channel to a second plurality of die stacks comprising at least two of the first die stack, the second die stack, and the third die stack; and depositing a casing material on the first substrate surface to encapsulate the first die stack, the second die stack, and the third die stack.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a circuit substrate comprising a first substrate surface and a second substrate surface arranged opposite to the first substrate surface;
a first die stack arranged on the first substrate surface, wherein the first die stack comprises a first plurality of dies;
a second die stack arranged on the first substrate surface, wherein the second die stack comprises a second plurality of dies;
a third die stack arranged on the first substrate surface, wherein the third die stack comprises a third plurality of dies;
a package casing disposed over the first substrate surface, wherein the package casing encapsulates the first die stack, the second die stack, and the third die stack, and covers at least part of the first substrate surface;
a plurality of conductive interconnect structures coupled to the second substrate surface;
a first signal channel including a first subset of conductive interconnect structures of the plurality of conductive interconnect structures; and
a second signal channel including a second subset of conductive interconnect structures of the plurality of conductive interconnect structures,
wherein the first signal channel is electrically coupled to a first plurality of die stacks comprising at least two of the first die stack, the second die stack, and the third die stack,
wherein the second signal channel is electrically coupled to a second plurality of die stacks comprising at least two of the first die stack, the second die stack, and the third die stack, and
wherein the first die stack, the second die stack, and the third die stack are laterally separated from each other on the first substrate surface.

2. The semiconductor device assembly of claim 1, wherein the first signal channel is electrically coupled to each die of the first plurality of dies and a first die of the second plurality of dies, and
wherein the second signal channel is electrically coupled to each die of the third plurality of dies and a second die of the second plurality of dies.

3. The semiconductor device assembly of claim 1, wherein the first signal channel is electrically coupled to each die of the first plurality of dies and a first die of the third plurality of dies, and
wherein the second signal channel is electrically coupled to each die of the second plurality of dies and a second die of the third plurality of dies.

4. The semiconductor device assembly of claim 1, wherein the first signal channel is electrically coupled to a first die of the first plurality of dies, a first die of the second plurality of dies, and a first die of the third plurality of dies, and
wherein the second signal channel is electrically coupled to a second die of the first plurality of dies, a second die of the second plurality of dies, and a second die of the third plurality of dies.

5. The semiconductor device assembly of claim 1, wherein the first signal channel is electrically coupled to at least three dies of the first plurality of die stacks,
wherein the second signal channel is electrically coupled to at least three dies of the second plurality of die stacks, and
wherein the at least three dies of the first plurality of die stacks are different from the at least three dies of the second plurality of die stacks.

6. The semiconductor device assembly of claim 1, wherein the first plurality of dies includes:
a first die arranged on the first substrate surface and having a board-on-chip configuration; and
a second die arranged on the first die and having a chip-on-board configuration,
wherein the second plurality of dies includes:
a third die arranged on the first substrate surface and having the board-on-chip configuration; and
a fourth die arranged on the third die and having the chip-on-board configuration,
wherein the third plurality of dies includes:
a fifth die arranged on the first substrate surface and having the board-on-chip configuration; and
a sixth die arranged on the fifth die and having the chip-on-board configuration,
wherein the first signal channel is electrically coupled to at least three dies of the first plurality of die stacks,
wherein the second signal channel is electrically coupled to at least three dies of the second plurality of die stacks, and
wherein the at least three dies of the first plurality of die stacks are different from the at least three dies of the second plurality of die stacks.

7. The semiconductor device assembly of claim 1, wherein the first plurality of dies includes:
a first die arranged on the first substrate surface and having a board-on-chip configuration;
a second die arranged on the first die and having a chip-on-board configuration; and
a third die arranged on the second die and having the chip-on-board configuration,
wherein the second plurality of dies includes:
a fourth die arranged on the first substrate surface and having the board-on-chip configuration;
a fifth die arranged on the fourth die and having the chip-on-board configuration; and
a sixth die arranged on the fifth die and having the chip-on-board configuration,
wherein the third plurality of dies includes:
a seventh die arranged on the first substrate surface and having the board-on-chip configuration;
an eighth die arranged on the seventh die and having the chip-on-board configuration; and
a ninth die arranged on the eighth die and having the chip-on-board configuration,
wherein the first signal channel is electrically coupled to at least three dies of the first plurality of die stacks,
wherein the second signal channel is electrically coupled to at least three dies of the second plurality of die stacks, and
wherein the at least three dies of the first plurality of die stacks are different from the at least three dies of the second plurality of die stacks.

8. The semiconductor device assembly of claim 7, wherein the first signal channel is electrically coupled to at least four dies of the first plurality of die stacks,
wherein the second signal channel is electrically coupled to at least four dies of the second plurality of die stacks, and
wherein the at least four dies of the first plurality of die stacks are different from the at least four dies of the second plurality of die stacks.

9. The semiconductor device assembly of claim 1, wherein the first plurality of dies includes:
a first pair of face-to-face coupled dies arranged on the first substrate surface; and
a second pair of face-to-face coupled dies arranged on the first pair of face-to-face coupled dies,
wherein the second plurality of dies includes:
a third pair of face-to-face coupled dies arranged on the first substrate surface; and
a fourth pair of face-to-face coupled dies arranged on the third pair of face-to-face coupled dies,
wherein the third plurality of dies includes:
a fifth pair of face-to-face coupled dies arranged on the first substrate surface; and
a sixth pair of face-to-face coupled dies arranged on the fifth pair of face-to-face coupled dies,
wherein the first signal channel is electrically coupled to at least three dies of the first plurality of die stacks,
wherein the second signal channel is electrically coupled to at least three dies of the second plurality of die stacks, and
wherein the at least three dies of the first plurality of die stacks are different from the at least three dies of the second plurality of die stacks.

10. The semiconductor device assembly of claim 9, wherein the first signal channel is electrically coupled to at least six dies of the first plurality of die stacks,
wherein the second signal channel is electrically coupled to at least six dies of the second plurality of die stacks, and
wherein the at least six dies of the first plurality of die stacks are different from the at least six dies of the second plurality of die stacks.

11. The semiconductor device assembly of claim 1, wherein the first signal channel includes a first plurality of bond wires connected to the first subset of conductive interconnect structures and the first plurality of die stacks, and
wherein the second signal channel includes a second plurality of bond wires connected to the second subset of conductive interconnect structures and the second plurality of die stacks.

12. The semiconductor device assembly of claim 1, wherein the first plurality of dies, the second plurality of dies, and the third plurality of dies are memory dies.

13. The semiconductor device assembly of claim 12, wherein the memory dies are NAND memory dies or dynamic random-access memory (DRAM) memory dies.

14. The semiconductor device assembly of claim 1, wherein the first signal channel is a first memory channel, and
wherein the second signal channel is a second memory channel.

15. The semiconductor device assembly of claim 1, wherein the first signal channel is a first data channel, and
wherein the second signal channel is a second data channel.

16. A memory device, comprising:
a circuit substrate comprising a first substrate surface and a second substrate surface arranged opposite to the first substrate surface;
a first die stack arranged on the first substrate surface, wherein the first die stack comprises a first plurality of memory dies;
a second die stack arranged on the first substrate surface, wherein the second die stack comprises a second plurality of memory dies;
a third die stack arranged on the first substrate surface, wherein the third die stack comprises a third plurality of memory dies;
a package casing disposed over the first substrate surface, wherein the package casing encapsulates the first die stack, the second die stack, and the third die stack, and covers at least part of the first substrate surface;
a first data channel including a first plurality of conductive interconnect structures coupled to the second substrate surface; and
a second data channel including a second plurality of conductive interconnect structures coupled to the second substrate surface,
wherein the first data channel is electrically coupled to a first plurality of die stacks comprising at least two of the first die stack, the second die stack, and the third die stack,
wherein the second data channel is electrically coupled to a second plurality of die stacks comprising at least two of the first die stack, the second die stack, and the third die stack, and
wherein the first die stack, the second die stack, and the third die stack are laterally separated from each other on the first substrate surface.

17. The memory device of claim 16, wherein the first plurality of conductive interconnect structures and the second plurality of conductive interconnect structures are solder balls.

18. The memory device of claim 16, wherein the first data channel is electrically coupled to at least three dies of the first plurality of die stacks,
wherein the second data channel is electrically coupled to at least three dies of the second plurality of die stacks, and
wherein the at least three dies of the first plurality of die stacks are different from the at least three dies of the second plurality of die stacks.

19. A method, comprising:
attaching a first die stack, a second die stack, and a third die stack to a first substrate surface of a circuit substrate, wherein the first die stack comprises a first plurality of dies, the second die stack comprises a second plurality of dies, and the third die stack comprises a third plurality of dies, and wherein the first die stack, the second die stack, and the third die stack are laterally separated from each other on the first substrate surface;
attaching a plurality of conductive interconnect structures to a second substrate surface of the circuit substrate;
forming a first signal channel including a first subset of conductive interconnect structures of the plurality of conductive interconnect structures;
forming a second signal channel including a second subset of conductive interconnect structures of the plurality of conductive interconnect structure;
electrically connecting the first signal channel to a first plurality of die stacks comprising at least two of the first die stack, the second die stack, and the third die stack;
electrically connecting the second signal channel to a second plurality of die stacks comprising at least two of the first die stack, the second die stack, and the third die stack; and
depositing a casing material on the first substrate surface to encapsulate the first die stack, the second die stack, and the third die stack.

20. The method of claim 19, wherein the first signal channel is electrically coupled to at least three dies of the first plurality of die stacks,
wherein the second signal channel is electrically coupled to at least three dies of the second plurality of die stacks, and
wherein the at least three dies of the first plurality of die stacks are different from the at least three dies of the second plurality of die stacks.
